(19) United States
(12) Patent Application Publication
(10) Pub. No.: US 2026/0271326 A1
(43) Pub. Date: Sep. 10, 2026

(54) SEMICONDUCTOR DEVICE

(71) Applicant: Kabushiki Kaisha Toshiba, Kawasaki-shi (JP)

(72) Inventor: Peitsen WU, Kawasaki Kanagawa (JP)

(21) Appl. No.: 19/544,281

(22) Filed: Feb. 19, 2026

(30) Foreign Application Priority Data
Feb. 21, 2025 (JP) 2025-026912

(51) Int. Cl. H10D 30/47; H10D 62/10; H10D 62/40; H10D 62/60; H10D 62/824; H10D 64/27; H10D 64/68

(52) U.S. Cl. CPC H10D 30/475; H10D 30/476; H10D 62/102; H10D 62/124; H10D 62/405; H10D 62/60; H10D 62/824; H10D 64/514; H10D 64/518; H10D 64/685; H10D 64/693

(57) ABSTRACT

According to one embodiment, there is provided a semiconductor device which includes first to third electrodes, a semiconductor member, and an insulating member. The semiconductor member includes a first semiconductor region including Alₓ₁Ga₁₋ₓ₁N (0≤x1<1), a second semiconductor region including Alₓ₂Ga₁₋ₓ₂N (0≤x2<1), and a third semiconductor region including Alₓ₃Ga₁₋ₓ₃N (0<x3≤1, x1<x3, x2<x3). The <0001> orientation of the second semiconductor region is opposite to the <0001> orientation of the first semiconductor region.

### CROSS-REFERENCE TO RELATED APPLICATION(S)

This application is based upon and claims the benefit of priority from Japanese Patent Application No. 2025-026912, filed Feb. 21, 2025, the entire contents of which are incorporated herein by reference.

### FIELD

Embodiments of the present invention relate to a semiconductor device.

### BACKGROUND

For example, it is desirable to improve characteristics of a semiconductor device such as a transistor.

### BRIEF DESCRIPTION OF THE DRAWINGS

FIG. 1 is a schematic cross sectional diagram illustrating a semiconductor device according to a first embodiment.

FIG. 2 is an example of a part of the semiconductor device according to the first embodiment.

FIG. 3 is a graph illustrating characteristics of the semiconductor device according to the first embodiment.

FIG. 4 is a graph illustrating characteristics of the semiconductor device according to the first embodiment.

FIG. 5 is a schematic cross sectional diagram illustrating a semiconductor device according to the first embodiment.

### DETAILED DESCRIPTION

In general, according to one embodiment, there is provided a semiconductor device which includes a first electrode, a second electrode, a third electrode, a semiconductor member, and a first insulating member. A direction from the first electrode toward the second electrode is aligned with a first direction. The third electrode includes a first electrode portion. A third electrode position in the first direction of the first electrode portion is between a first electrode position in the first direction of the first electrode and a second electrode position in the first direction of the second electrode. The semiconductor member includes a first semiconductor region including Alₓ₁Ga₁₋ₓ₁N (0≤x1<1), a second semiconductor region including Alₓ₂Ga₁₋ₓ₂N (0≤x2<1), and a third semiconductor region including and Alₓ₃Ga₁₋ₓ₃N (0<x3≤1, x1<x3, x2<x3). The first semiconductor region includes a first partial region, a second partial region, a third partial region, a fourth partial region, and a fifth partial region. A direction from the first partial region toward the first electrode is aligned with a second direction intersecting the first direction. A direction from the second partial region toward the second electrode is aligned with the second direction. A direction from the third partial region toward the first electrode portion is aligned with the second direction. A fourth partial region position in the first direction of the fourth partial region is between a first partial region position in the first direction of the first partial region and a third partial region position in the first direction of the third partial region. A fifth partial region position in the first direction of the fifth partial region is between the third partial region position and a second partial region position in the first direction of the second partial region. The second semiconductor region includes a first semiconductor portion and a second semiconductor portion. A direction from the fourth partial region toward the first semiconductor portion is aligned with the second direction. A direction from the fifth partial region toward the second semiconductor portion is aligned with the second direction. A <0001> orientation of the second semiconductor region is opposite to a <0001> orientation of the first semiconductor region. The third semiconductor region includes a first region, a second region, a third region, a fourth region, and a fifth region. The first semiconductor portion is between the fourth partial region and the first region in the second direction. The second semiconductor portion is between the fifth partial region and the second region in the second direction. The third region is between the third partial region and the first electrode portion in the second direction. The fourth region is between the first semiconductor portion and the first electrode portion in the first direction. The fifth region is between the first electrode portion and the second semiconductor portion in the first direction. At least a portion of the first insulating member is between the semiconductor member and the third electrode.

Hereinafter, embodiments of the present invention will be described with reference to the drawings. The drawings are schematic or conceptual, and the relationship between the thickness and width of each portion, the ratio of the sizes between portions, and the like are not necessarily the same as the actual ones. Even when the same portion is illustrated, the dimensions and ratios may be illustrated differently depending on the drawings. In the specification and the drawings, the same reference numerals are given to the same elements as those described above with reference to the drawings that have already been referred to, and detailed description thereof will be omitted as appropriate.

### First Embodiment

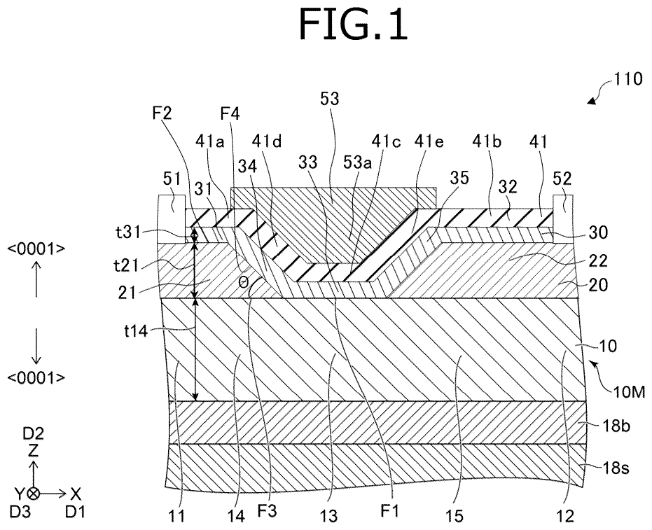

FIG. 1 is a schematic cross sectional diagram illustrating a semiconductor device according to a first embodiment. As shown in FIG. 1, the semiconductor device 110 according to the embodiment includes a first electrode 51, a second electrode 52, a third electrode 53, a semiconductor member 10M, and a first insulating member 41.

The direction from the first electrode 51 toward the second electrode 52 is aligned with the first direction D1. The first direction D1 is taken as an X-axis direction. One direction perpendicular to the X-axis direction is taken as a Z-axis direction. A direction perpendicular to the X-axis direction and the Z-axis direction is defined as a Y-axis direction.

The third electrode 53 includes a first electrode portions 53a. The position (the third electrode position) of the first electrode portion 53a in the first direction D1 is between the position (the first electrode position) of the first electrode 51 in the first direction D1 and the position (the second electrode position) of the second electrode 52 in the first direction D1. For example, the third electrode 53 is between the first electrode 51 and the second electrode 52 in the first direction D1.

The semiconductor member 10M includes a first semiconductor region 10, a second semiconductor region 20, and a third semiconductor region 30.

The first semiconductor region 10 includes Alₓ₁Ga₁₋ₓ₁N (0≤x1<1). The composition ratio x1 may be, for example, not less than 0 and not more than 0.1. The first semiconductor region 10 may include, for example, GaN.

The first semiconductor region 10 includes a first partial region 11, a second partial region 12, a third partial region 13, a fourth partial region 14, and a fifth partial region 15. The direction from the first partial region 11 toward the first electrode 51 is aligned with the second direction D2 intersecting the first direction D1. The second direction D2 may be, for example, the Z-axis direction.

The direction from the second partial region 12 toward the second electrode 52 is aligned with the second direction D2. The direction from the third partial region 13 toward the first electrode portion 53a is aligned with the second direction D2.

The position (the fourth partial region position) of the fourth partial region 14 in the first direction D1 is between the position (the first partial region position) of the first partial region 11 in the first direction D1 and the position (the third partial region position) of the third partial region 13 in the first direction D1. The position (the fifth partial region position) of the fifth partial region 15 in the first direction D1 is between the third partial region position and the position (the second partial region position) of the second partial region 12 in the first direction D1.

The first partial region 11 is a region overlapping the first electrode 51 in the second direction D2. The second partial region 12 is a region overlapping the second electrode 52 in the second direction D2. The third partial region 13 is a region overlapping the first electrode portion 53a in the second direction D2. The boundaries between the plurality of partial regions may be unclear.

The second semiconductor region 20 includes Alₓ₂Ga₁₋ₓ₂N (0≤x2<1). The composition ratio x2 may be, for example, not less than 0 and not more than 0.1. The composition ratio x1 may be substantially the same as the composition ratio x2. The second semiconductor region 20 may include, for example, GaN.

The second semiconductor region 20 includes a first semiconductor portion 21 and a second semiconductor portion 22. The direction from the fourth partial region 14 toward the first semiconductor portion 21 is aligned with the second direction D2. The direction from the fifth partial region 15 toward the second semiconductor portion 22 is aligned with the second direction D2.

The <0001> orientation of the second semiconductor region 20 is opposite to the <0001> orientation of the first semiconductor region 10. In the example of FIG. 1, the <0001> orientation of the first semiconductor region 10 is aligned with the first orientation (−Z) from the first semiconductor portion 21 toward the fourth partial region 14. The <0001> orientation of the second semiconductor region 20 is aligned with the second orientation (+Z) from the fourth partial region 14 toward the first semiconductor portion 21.

The third semiconductor region 30 includes Alₓ₃Ga₁₋ₓ₃N (0<x3≤1, x1<x3, x2<x3). The composition ratio x3 may be, for example, the composition ratio x3 is not less than 0.15 and not more than 1. The third semiconductor region 30 includes, for example, AlGaN or AlN.

The third semiconductor region 30 includes a first region 31, a second region 32, a third region 33, a fourth region 34, and a fifth region 35. The first semiconductor portion 21 is between the fourth partial region 14 and the first region 31 in the second direction D2. The second semiconductor portion 22 is between the fifth partial region 15 and the second region 32 in the second direction D2. The third region 33 is between the third partial region 13 and the first electrode portion 53a in the second direction D2.

The fourth region 34 is between the first semiconductor portion 21 and the first electrode portion 53a in the first direction D1. The fifth region 35 is between the first electrode portion 53a and the second semiconductor portion 22 in the first direction D1.

At least a portion of the first insulating member 41 is between the semiconductor member 10M portion and the third electrode 53.

The current that flows between the first electrode 51 and the second electrode 52 is controlled by the potential of the third electrode 53. The potential of the third electrode 53 may be, for example, a potential referenced to the potential of the first electrode 51. For example, the first electrode 51 functions as a source electrode. For example, the second electrode 52 functions as a drain electrode. For example, the third electrode 53 functions as a gate electrode. The semiconductor device 110 is a transistor.

The second semiconductor region 20 includes a second surface F2 opposing the first region 31 and the second region 32. A first carrier region is formed in the vicinity of the second surface F2. The first carrier region is, for example, a Two-Dimensional Electron Gas. A current flows by the first carrier region. For example, the operation of a high electron mobility transistor (HEMT) may be applied to the semiconductor device 110.

As described above, the first semiconductor region 10 having different crystal orientations as described above is provided in the semiconductor device 110. Thereby, a high threshold voltage is stably obtained. According to the embodiment, a semiconductor device can be provided in which the characteristics can be improved.

A high threshold voltage is obtained by the first semiconductor region 10 having the reverse crystal orientation. For example, it is considered that the first semiconductor region 10 having the reverse crystal orientation functions as a back gate.

For example, the third partial region 13 includes the first surface F1 opposing the third region 33. For example, it is considered that the second carrier region is formed in the vicinity of the first surface F1. For example, it is considered that the second carrier region includes a Two-Dimensional Hole Gas. It is considered that a high threshold voltage is thereby obtained.

In the first reference example, a GaN layer including a p-type impurity is provided as a back gate. A high threshold voltage is obtained in the first reference example as well. However, in the first reference example, the crystallinity is likely to be low due to the p-type impurity (Mg). The p-type impurity hinders the movement of carriers. Therefore, it is difficult to obtain high mobility. The on-resistance is high in the first reference example. In the first reference example, the threshold voltage variation is large, and the stability of the characteristics is insufficient.

In the embodiment, the p-type impurity may not be introduced. Thereby, high crystallinity is obtained. High mobility is obtained. A low on-resistance is obtained. According to the embodiment, a semiconductor device can be provided in which the characteristics can be improved.

In the embodiment, the first semiconductor region 10 does not include a p-type impurity. Or, the concentration of the p-type impurity in the first semiconductor region 10 is less than 1×10¹⁷cm⁻³. The p-type impurity includes, for example, at least one selected from the group consisting of Mg, Zn, and Be. High crystallinity is obtained. High mobility is obtained. A low on-resistance is obtained.

The <0001> orientation of the first region 31 may be the same orientation as the <0001> orientation of the second semiconductor region 20. The <0001> orientation of the second region 32 may be the same orientation as the <0001> orientation of the second semiconductor region 20.

On the other hand, the <0001> orientation of the third region 33 may be the same orientation as the <0001> orientation of the first semiconductor region 10.

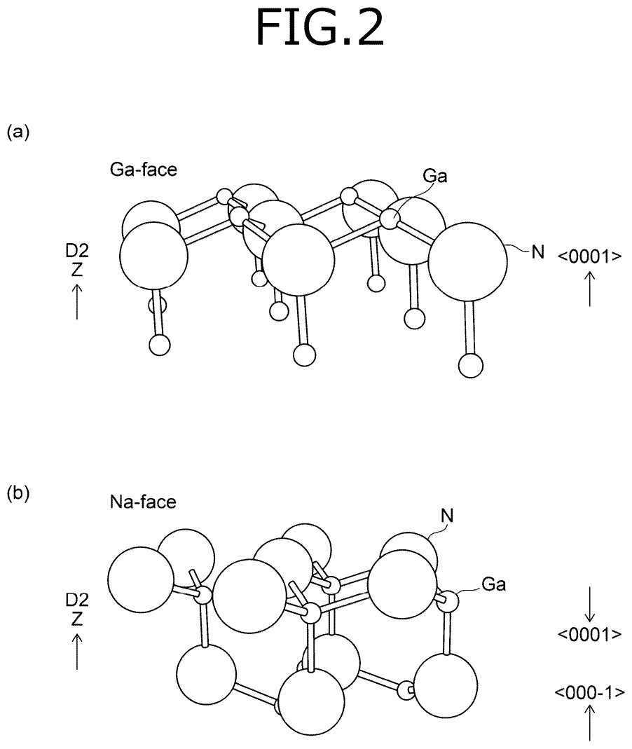

FIG. 2 is a schematic diagrams illustrating a portion of the semiconductor device according to the first embodiment.

This figure illustrates two crystal orientations. FIG. 2(a) corresponds to the Ga-face. FIG. 2(b) corresponds to the N-face. For example, the <0001> orientation corresponds to the Ga-face. For example, the <000-1> orientation corresponds to the N-face.

As shown in FIG. 1, the third partial region 13 includes a first surface F1 opposing the third region 33. The first surface F1 is, for example, an N-face. The second semiconductor region 20 includes a second surface F2 opposing the first region 31 and the second region 32. The second surface F2 is, for example, a Ga-face.

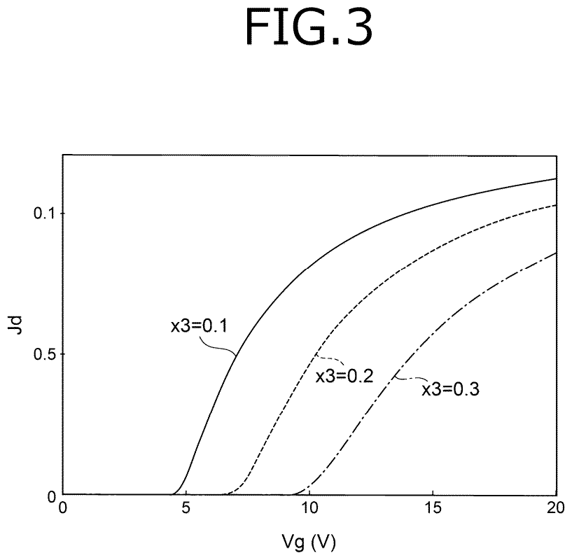

FIG. 3 is a graph illustrating characteristics of the semiconductor device according to the first embodiment. The horizontal axis of FIG. 3 is the gate voltage Vg. The vertical axis is the current density Jd. The current density Jd is normalized and displayed. As shown in FIG. 3, the threshold voltage increases as the composition ratio x3 increases. In the embodiment, the composition ratio x3 may be, for example, not less than 0.1 and not more than 0.2. A practical high threshold voltage is obtained.

As shown in FIG. 1, the fourth partial region 14 includes a third surface F3 opposing the first semiconductor portion 21. The first semiconductor portion 21 includes a fourth surface F4 opposing the fourth region 34. The fourth surface F4 may be inclined with respect to the third surface F3. For example, a tapered side surface may be provided.

For example, the angle between the fourth surface F4 and the third surface F3 is taken as an angle θ. In the embodiment, the angle θ may be, for example, greater than 0 degrees and less than or equal to 45 degrees. The inclined side surfaces provide good electrical properties.

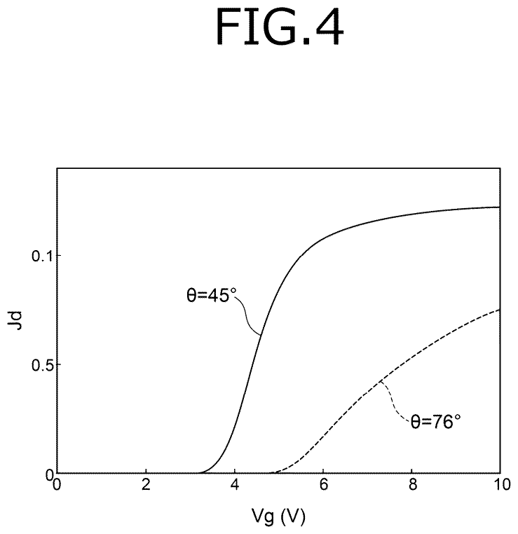

FIG. 4 is a graph illustrating characteristics of the semiconductor device according to the first embodiment. The horizontal axis of FIG. 4 is the gate voltage Vg. The vertical axis is the current density Jd. The current density Jd is normalized and displayed. As shown in FIG. 4, a high threshold voltage is obtained when the angle θ is high. In the embodiment, the angle θ may be, for example, not less than 45 degrees and less than 90 degrees. A practical high threshold voltage is stably obtained.

As shown in FIG. 1, the thickness of the first semiconductor portion 21 along the second direction D2 is taken as a first semiconductor portion thickness t21. The thickness of the first region 31 along the second direction D2 is taken as a first region thickness t31. In the embodiment, the first semiconductor portion thickness t21 may be thicker than the first region thickness t31. Stable characteristics are easily obtained.

The first semiconductor portion thickness t21 may be, for example, equal to or greater than 10 nm and equal to or less than 200 nm. The first region thickness t31 may be, for example, equal to or greater than 1 nm and equal to or less than 20 nm. The first semiconductor portion thickness t21 may be, for example, equal to or greater than 15 nm and equal to or less than 200 nm. The first region thickness t31 may be, for example, equal to or greater than 1 nm and less than 15 nm.

The thickness of the fourth partial region 14 in the second direction D2 is taken as a fourth partial region thickness t14. The fourth partial region thickness t14 may be thicker than the first semiconductor portion thickness t21 of the first semiconductor portion 21 in the second direction D2. For example, the fourth partial region thickness t14 may be not less than 50 nm and not more than 10 μm.

In the embodiment, the first insulating member 41 may include silicon and at least one first element selected from the group consisting of oxygen and nitrogen. The first insulating member 41 may include, for example, at least one selected from the group consisting of silicon oxide, silicon nitride, and silicon oxynitride.

As shown in FIG. 1, the first insulating member 41 may include a first insulating region 41a, a second insulating region 41b, a third insulating region 41c, a fourth insulating region 41d, and a fifth insulating region 41e.

The first region 31 is between the first semiconductor portion 21 and the first insulating region 41a in the second direction D2. The second region 32 is between the second semiconductor portion 22 and the second insulating region 41b in the second direction D2. The third insulating region 41c is between the third region 33 and the first electrode portion 53a in the second direction D2. The fourth insulating region 41d is between the fourth region 34 and the first electrode portion 53a in the first direction D1. The fifth insulating region 41e is between the first electrode portion 53a and the fifth region 35 in the first direction D1.

For example, the first electrode 51 is electrically connected to the first partial region 11. The second electrode 52 is electrically connected to the second partial region 12. The first electrode 51 may be electrically connected to the first semiconductor portion 21. The second electrode 52 may be electrically connected to the second semiconductor portion 22.

The first electrode 51, the second electrode 52, and the third electrode 53 may extend along the third direction D3. The third direction D3 intersects a plane including the first direction D1 and the second direction D2.

As shown in FIG. 1, the semiconductor device 110 may include a substrate 18s and a nitride layer 18b. A nitride layer 18b is provided between the substrate 18s and the semiconductor member 10M. The substrate 18s may include, for example, at least one selected from the group consisting of sapphire, SiC, GaN, and silicon. The nitride layer 18b includes, for example, Al, Ga, and N. The nitride layer 18b is, for example, a buffer layer.

In one example, the surface of the first semiconductor region 10 is processed by oxygen or the like, and then the second semiconductor region 20 may be formed. This results in two semiconductor regions of opposite polarity. The first semiconductor region 10 may be formed on the back surface of a general wafer.

### Second Embodiment

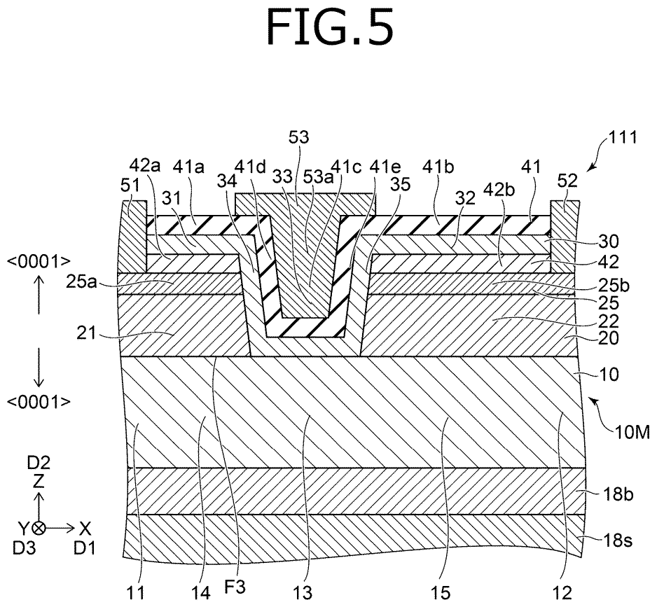

FIG. 5 is a schematic cross sectional diagram illustrating a semiconductor device according to the first embodiment. As shown in FIG. 5, the semiconductor member 10M of the semiconductor device 111 according to the embodiment further includes an intermediate semiconductor region 25. The configuration of the semiconductor device 111, excluding this, may be similar to that of the semiconductor device 110.

In the device 111, the intermediate semiconductor region 25 includes Alₓ₄Ga₁₋ₓ₄N (0≤x4<1). The intermediate semiconductor region 25 includes AlGaN or AlN. The intermediate semiconductor region 25 includes a first intermediate semiconductor portion 25a and a second intermediate semiconductor portion 25b. The first semiconductor portion 21 is between the fourth partial region 14 and the first intermediate semiconductor portion 25a in the second direction D2. The second semiconductor portion 22 is between the fifth partial region 15 and the second intermediate semiconductor portion 25b in the second direction D2. In the semiconductor device 111, a high threshold voltage is obtained stably. A semiconductor device capable of improving characteristics can be provided.

The <0001> orientation of the intermediate semiconductor region 25 is aligned with the first orientation from the fourth partial region 14 toward the first semiconductor portion 21.

As shown in FIG. 5, the semiconductor device 111 may further include a second insulating member 42. The second insulating member 42 includes a first insulating portion 42a and a second insulating portion 42b. The first insulating portion 42a is between the first intermediate semiconductor portion 25a and the first region 31 in the second direction D2. The second insulating portion 42b is between the second intermediate semiconductor portion 25b and the second region 32 in the second direction D2.

In the embodiment, the information relating to the shape of the semiconductor region, etc., is obtained by, for example, electron microscope observation, etc. Information on the composition and the element concentration in the semiconductor region is obtained by, for example, energy dispersive X-ray spectroscopy (EDX), secondary ion mass spectrometry (SIMS), or the like. The information on the composition of the semiconductor region may be obtained by, for example, reciprocal space mapping.

Hereinafter, the invention of the embodiment will be described below.
<1>

A semiconductor device comprising:
a first electrode,
a second electrode, a direction from the first electrode toward the second electrode being aligned with a first direction,
a third electrode including a first electrode portion, a third electrode position in the first direction of the first electrode portion being between a first electrode position in the first direction of the first electrode and a second electrode position in the first direction of the second electrode,
a semiconductor member,
a first insulating member, wherein
the semiconductor member includes
   a first semiconductor region including Alₓ₁Ga₁₋ₓ₁N (0≤x1<1), the first semiconductor region including a first partial region, a second partial region, a third partial region, a fourth partial region, and a fifth partial region, a direction from the first partial region toward the first electrode being along a second direction intersecting the first direction, a direction from the second partial region toward the second electrode being along the second direction, a direction from the third partial region toward the first electrode portion being along the second direction, a fourth partial region position of the fourth partial region in the first direction being between a first partial region position of the first partial region in the first direction and a third partial region position of the third partial region in the first direction, and a fifth partial region position of the fifth partial region in the first direction being between the third partial region position and a second partial region position of the second partial region in the first direction,
   a second semiconductor region including Alₓ₂Ga₁₋ₓ₂N (0≤x2<1), the second semiconductor region including a first semiconductor portion and a second semiconductor portion, a direction from the fourth partial region toward the first semiconductor portion being aligned with the second direction, a direction from the fifth partial region toward the second semiconductor portion being aligned with the second direction, a <0001> orientation of the second semiconductor region being opposite to a <0001> orientation of the first semiconductor region,
   a third semiconductor region including Alₓ₃Ga₁₋ₓ₃N (0<x3≤1, x1<x3, x2<x3), the third semiconductor region including a first region, a second region, a third region, a fourth region, and a fifth region, the first semiconductor portion being between the fourth partial region and the first region in the second direction, the second semiconductor portion being between the fifth partial region and the second region in the second direction, the third region being between the third partial region and the first electrode portion in the second direction, the fourth region being between the first semiconductor portion and the first electrode portion in the first direction, the fifth region being between the first electrode portion and the second semiconductor portion in the first direction, and
   at least a portion of the first insulating member being between the semiconductor member and the third electrode.
<2>

The semiconductor device according to <1>, wherein
the <0001> orientation of the first semiconductor region is aligned with a first orientation from the first semiconductor portion toward the fourth partial region, and the <0001> orientation of the second semiconductor region is aligned with a second orientation from the fourth partial region toward the first semiconductor portion.
<3>

The semiconductor device according to <2>, wherein
a <0001> orientation of the first region has the same orientation as the <0001> orientation of the second semiconductor region, and
a <0001> orientation of the second region is the same as the <0001> orientation of the second semiconductor region.
<4>

The semiconductor device according to <3>, wherein
a <0001> orientation of the third region is the same as the <0001> orientation of the first semiconductor region.
<5>

The semiconductor device according to any one of <1> to <4>, further comprising
the semiconductor member including an intermediate semiconductor region including Alₓ₄Ga₁₋ₓ₄N (0≤x4<1), wherein
the intermediate semiconductor region includes a first intermediate semiconductor portion and a second intermediate semiconductor portion,
the first semiconductor portion being between the fourth partial region and the first intermediate semiconductor portion in the second direction, and
the second semiconductor portion being between the fifth partial region and the second intermediate semiconductor portion in the second direction.
<6>

The semiconductor device according to <5>, further comprising
a second insulating member, wherein
the second insulating member includes a first insulating portion and a second insulating portion,
the first insulating portion is between the first intermediate semiconductor portion and the first region in the second direction, and
the second insulating portion is between the second intermediate semiconductor portion and the second region in the second direction.
<7>

The semiconductor device according to <1> or <4>, wherein
the third partial region includes a first surface opposing the third region, and
the first surface is an N surface.
<8>

The semiconductor device according to <7>, wherein
the second semiconductor region includes a second surface opposing the first region and the second region, and
the second surface is a Ga surface.
<9>

The semiconductor device according to any one of <1> to <8>, wherein
the fourth partial region includes a third surface opposing the first semiconductor portion,
the first semiconductor portion includes a fourth surface opposing the fourth region, and
the fourth surface is inclined with respect to the third surface.
<10>

The semiconductor device according to <9>, wherein
an angle between the fourth surface and the third surface is 45 degrees or more and less than 90 degrees.
<11>

The device according to any one of <1> to <9>, wherein
the x1 is the same as the x2.
<12>

The device according to any one of <1> to <10>, wherein
the x3 is 0.15 or more and 1 or less.
<13>

The semiconductor device according to any one of <1> to <12>, wherein
a first semiconductor portion thickness of the first semiconductor portion along the second direction is thicker than a first region thickness of the first region along the second direction.
<14>

The device according to <13>, wherein
the first semiconductor portion thickness is equal to or larger than 15 nm and equal to or smaller than 200 nm, and
the first region thickness is equal to or greater than 1 nm and less than 15 nm.
<15>

The semiconductor device according to any one of <1> to <12>, wherein
a fourth partial region thickness along the second direction of the fourth partial region is thicker than a first semiconductor portion thickness along the second direction of the first semiconductor portion.
<16>

The semiconductor device according to any one of <1> to <15>, wherein
the first insulating member includes silicon and at least one first element selected from the group consisting of oxygen and nitrogen.
<17>

The semiconductor device according to any one of <1> to <16>, wherein
the first insulating member includes a first insulating region, a second insulating region, a third insulating region, a fourth insulating region, and a fifth insulating region,
the first region being between the first semiconductor portion and the first insulating region in the second direction,
the second region being between the second semiconductor portion and the second insulating region in the second direction,
the third insulating region being between the third region and the first electrode portion in the second direction,
the fourth insulating region being between the fourth region and the first electrode portion in the first direction, and
the fifth insulating region is between the first electrode portion and the fifth region in the first direction.
<18>

The semiconductor device according to any one of <1> to <17>, wherein
the first electrode is electrically connected to the first semiconductor portion, and
the second electrode is electrically connected to the second semiconductor portion.
<19>

The semiconductor device according to any one of <1> to <18>, wherein
the first semiconductor region either does not include a p-type impurity, or includes it a concentration less than 1×10¹⁷ cm⁻³.
<20>

The semiconductor device according to <19>, wherein
the p-type impurity includes at least one selected from the group consisting of Mg, Zn, and Be.

According to the embodiment, a semiconductor device is provided in which the characteristics can be improved.

In the specification of the present application, the “state of being electrically connected” includes a state in which a plurality of conductors are physically in contact with each other and a current flows between the plurality of conductors. The “state of being electrically connected” includes a state in which another conductor is inserted between a plurality of conductors and a current flows between the plurality of conductors.

The embodiments of the present invention have been described above with reference to specific examples. However, the present invention is not limited to these specific examples. For example, one skilled in the art may similarly practice the invention by appropriately selecting specific configurations of components included in semiconductor devices such as electrodes, semiconductor members, semiconductor regions, insulating members, etc., from known art; and such practice is included in the scope of the invention to the extent that similar effects can be obtained.

In addition, combinations of any two or more elements of the specific examples within a technically possible range are also included in the scope of the present invention as long as the gist of the present invention is included.

Moreover, all semiconductor devices practicable by an appropriate design modification by one skilled in the art based on the semiconductor devices described above as embodiments of the invention also are within the scope of the invention to the extent that the spirit of the invention is included.

In addition, within the scope of the idea of the present invention, those skilled in the art can conceive various changes and modifications, and it is understood that those changes and modifications also belong to the scope of the present invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. These embodiments and modifications thereof are included in the scope and gist of the invention, and are included in the invention described in the claims and the equivalent scope thereof.

What is claimed is:

1. A semiconductor device comprising:
a first electrode,
a second electrode, a direction from the first electrode toward the second electrode being aligned with a first direction,
a third electrode including a first electrode portion, a third electrode position in the first direction of the first electrode portion being between a first electrode position in the first direction of the first electrode and a second electrode position in the first direction of the second electrode,
a semiconductor member,
a first insulating member, wherein the semiconductor member includes
a first semiconductor region including Alₓ₁Ga₁₋ₓ₁N (0≤x1<1), the first semiconductor region including a first partial region, a second partial region, a third partial region, a fourth partial region, and a fifth partial region, a direction from the first partial region toward the first electrode being along a second direction intersecting the first direction, a direction from the second partial region toward the second electrode being along the second direction, a direction from the third partial region toward the first electrode portion being along the second direction, a fourth partial region position of the fourth partial region in the first direction being between a first partial region position of the first partial region in the first direction and a third partial region position of the third partial region in the first direction, and a fifth partial region position of the fifth partial region in the first direction being between the third partial region position and a second partial region position of the second partial region in the first direction,
a second semiconductor region including Alₓ₂Ga₁₋ₓ₂N (0≤x2<1), the second semiconductor region including a first semiconductor portion and a second semiconductor portion, a direction from the fourth partial region toward the first semiconductor portion being aligned with the second direction, a direction from the fifth partial region toward the second semiconductor portion being aligned with the second direction, a <0001> orientation of the second semiconductor region being opposite to a <0001> orientation of the first semiconductor region,
a third semiconductor region including Alₓ₃Ga₁₋ₓ₃N (0<x3≤1, x1<x3, x2<x3), the third semiconductor region including a first region, a second region, a third region, a fourth region, and a fifth region, the first semiconductor portion being between the fourth partial region and the first region in the second direction, the second semiconductor portion being between the fifth partial region and the second region in the second direction, the third region being between the third partial region and the first electrode portion in the second direction, the fourth region being between the first semiconductor portion and the first electrode portion in the first direction, the fifth region being between the first electrode portion and the second semiconductor portion in the first direction, and
at least a portion of the first insulating member being between the semiconductor member and the third electrode.

2. The semiconductor device according to claim 1, wherein
the <0001> orientation of the first semiconductor region is aligned with a first orientation from the first semiconductor portion toward the fourth partial region, and
the <0001> orientation of the second semiconductor region is aligned with a second orientation from the fourth partial region toward the first semiconductor portion.

3. The semiconductor device according to claim 2, wherein
a <0001> orientation of the first region has the same orientation as the <0001> orientation of the second semiconductor region, and
a <0001> orientation of the second region is the same as the <0001> orientation of the second semiconductor region.

4. The semiconductor device according to claim 3, wherein
a <0001> orientation of the third region is the same as the <0001> orientation of the first semiconductor region.

5. The semiconductor device according to claim 1, further comprising:
the semiconductor member including an intermediate semiconductor region including Alₓ₄Ga₁₋ₓ₄N (0≤x4<1), wherein
the intermediate semiconductor region includes a first intermediate semiconductor portion and a second intermediate semiconductor portion,
the first semiconductor portion being between the fourth partial region and the first intermediate semiconductor portion in the second direction, and
the second semiconductor portion being between the fifth partial region and the second intermediate semiconductor portion in the second direction.

6. The semiconductor device according to claim 5, further comprising:
a second insulating member, wherein
the second insulating member includes a first insulating portion and a second insulating portion,
the first insulating portion is between the first intermediate semiconductor portion and the first region in the second direction, and
the second insulating portion is between the second intermediate semiconductor portion and the second region in the second direction.

7. The semiconductor device according to claim 1, wherein
the third partial region includes a first surface opposing the third region, and
the first surface is an N surface.

8. The semiconductor device according to claim 7, wherein
the second semiconductor region includes a second surface opposing the first region and the second region, and
the second surface is a Ga surface.

9. The semiconductor device according to claim 1, wherein
the fourth partial region includes a third surface opposing the first semiconductor portion,
the first semiconductor portion includes a fourth surface opposing the fourth region, and
the fourth surface is inclined with respect to the third surface.

10. The semiconductor device according to claim 9, wherein
an angle between the fourth surface and the third surface is 45 degrees or more and less than 90 degrees.

11. The device according to claim 1, wherein
the x1 is the same as the x2.

12. The device according to claim 1, wherein
the x3 is 0.15 or more and 1 or less.

13. The semiconductor device according to claim 1, wherein
a first semiconductor portion thickness of the first semiconductor portion along the second direction is thicker than a first region thickness of the first region along the second direction.

14. The device according to claim 13, wherein
the first semiconductor portion thickness is equal to or larger than 15 nm and equal to or smaller than 200 nm, and
the first region thickness is equal to or greater than 1 nm and less than 15 nm.

15. The semiconductor device according to claim 1, wherein
a fourth partial region thickness along the second direction of the fourth partial region is thicker than a first semiconductor portion thickness along the second direction of the first semiconductor portion.

16. The semiconductor device according to claim 1, wherein
the first insulating member includes silicon and at least one first element selected from the group consisting of oxygen and nitrogen.

17. The semiconductor device according to claim 1, wherein
the first insulating member includes a first insulating region, a second insulating region, a third insulating region, a fourth insulating region, and a fifth insulating region,
the first region being between the first semiconductor portion and the first insulating region in the second direction,
the second region being between the second semiconductor portion and the second insulating region in the second direction,
the third insulating region being between the third region and the first electrode portion in the second direction,
the fourth insulating region being between the fourth region and the first electrode portion in the first direction, and
the fifth insulating region is between the first electrode portion and the fifth region in the first direction.

18. The semiconductor device according to claim 1, wherein
the first electrode is electrically connected to the first semiconductor portion, and
the second electrode is electrically connected to the second semiconductor portion.

19. The semiconductor device according to claim 1, wherein
the first semiconductor region either does not include a p-type impurity, or includes it a concentration less than 1×10¹⁷ cm⁻³.

20. The semiconductor device according to claim 19, wherein
the p-type impurity includes at least one selected from the group consisting of Mg, Zn, and Be.
